(19) United States
(12) Patent Application Publication
(10) Pub. No.: US 2005/0218394 A1
(43) Pub. Date: Oct. 6, 2005

(54) Micro electronic component

(76) Inventors: Gunther Schmid, Velbert (DE); Ulrich Simon, Aachen (DE); Dieter Jager, Duisburg-Rahm (DE); Venogopal Santhanam, Bangalore (IN)

Correspondence Address: WOODARD, EMHARDT, MORIARTY, MCNETT & HENRY LLP, BANK ONE CENTER/TOWER, 111 MONUMENT CIRCLE, SUITE 3700, INDIANAPOLIS, IN, 46204-5137, US

(21) Appl. No.: 11/093,196

(22) Filed: Mar. 29, 2005

(30) Foreign Application Priority Data
Mar. 31, 2004 (DE) 10 2004 016 534.3
Apr. 15, 2004 (DE) 10 2004 018 915.3
Jul. 22, 2004 (DE) 10 2004 035 615.7

(51) Int. Cl. H01L 47/00

(52) U.S. Cl. 257/4

(57) ABSTRACT

A micro electronic component, preferably in the form of an electronic memory, includes the use of clusters as an electronic memory. Also disclosed as part of the present invention is a method for fabricating a micro electronic component. The present invention contemplates fabrication of an especially compact electronic memory that works especially with single-electron transistors or single-electronic transfers. According to the present invention, clusters with a metallic cluster nucleus are arranged in parallel grooves essentially in lines or rows and are connected individually to first and second connecting electrodes, such that individually the clusters can be electrically modified or polled independently of each other.

### REFERENCE TO RELATED APPLICATIONS

The present application claims the benefit of German Patent Application Serial No. 10 2004 016 534.3, filed Mar. 31, 2004; German Patent Application Serial No. 10 2004 018 915.3, filed Apr. 15, 2004; and German Patent Application Serial No. 10 2004 035 615.7, filed Jul. 22, 2004, all of which are hereby incorporated by reference in their entirety.

### BACKGROUND OF THE INVENTION

The present invention relates to a micro electronic component, especially a memory, a use of clusters, and a method for fabricating a micro electronic component.

From DE 42 12 220 A1 (published Oct. 14, 1993 to Schmid et al.) and U.S. Pat. No. 5,350,930 A (issued Sep. 27, 1994 to Schmid et al.), a micro electronic component with at least one cluster and connecting electrodes is known. Here, micro-quantum channels are formed by at least two adjoining clusters. Preferably, bulk material of the clusters is used and this bulk material is pressed together. The clusters each have a metallic cluster nucleus and an insulating ligand shell. The cluster nuclei each have, in particular, 55 gold atoms in close-packed sphere packing. The known component achieves further miniaturization in the field of micro electronics. In comparison with typical space requirements of approximately 250 nm for transistors in previously known technology, the dimensions for the quantum wires of the known components can be reduced significantly.

In addition, intensive research has been performed in the field of metal clusters especially with 55 gold atoms. As examples of this research, the following articles are mentioned: “Single-electron tunneling in Au₅₅ cluster monolayers” by L. F. Chi et al., Appl. Phys. A 66, pp. 187-190 (1998); “Metal Clusters and Colloids,” Gunter Schmid et al., Adv. Mater. 1998, 10, No. 7; “Reduced Metallic Properties of Ligand-Stabilized Small Metal Clusters,” Huijing Zhang et al., NANO LETTERS 2003, Vol. 3, No. 3, 305-307.

The present invention is based on the problem of disclosing a micro electronic component and a method for fabricating a micro electronic component, wherein a micro electronic component can be realized, especially in the form of an electronic memory or with single-electron transistors, which has minimal space requirements, as well as minimal power and energy requirements, and which can be fabricated easily.

An essential idea of the present invention is to electrically connect clusters individually such that these can be electrically modified independently of each other and individually, especially through single-electron transfer, and/or their electrical state can be polled.

The individual, electrical modification and polling permits addressing, so that an electronic memory can be realized with a plurality of “memory cells” or transistors formed by the connected clusters.

Therefore, because only a single cluster is necessary for each memory cell or transistor, the space requirement is minimized.

The ideally provided single-electron transfer for changing the electrical or electronic state of a connected cluster minimizes the necessary power and energy requirements, so that very quick switching times can be realized and the low loss heat in contrast with conventional solutions enables miniaturization without cooling problems.

### SUMMARY OF THE INVENTION

In the preferred embodiments described in more detail below, not all of the clusters are connected electrically; instead only a few of the clusters are in contact with first and second connecting electrodes. Here, the non-connected clusters are not disturbed.

Furthermore, there can also be defective connections in so far as two connecting electrodes contact two parallel, adjacent clusters instead of an in-between cluster at an intersecting point. However, the likelihood of such a defect is sufficiently small and ideally negligible for a correspondingly small width of the connecting electrodes.

Preferably, the clusters are arranged essentially in lines or rows. According to a preferred embodiment, this is enabled very easily by housing the clusters in parallel grooves of equal size.

A very simple design and very simple bonding is preferably achieved by forming the first and second connecting electrodes in strips and arranging them such that the first connecting electrodes run parallel to each other and the second connecting electrodes run parallel to each other and crosswise to the first connecting electrodes, with a first and a second connecting electrode being in electrical contact with each other at their appropriate intersecting point preferably by means of a single cluster.

Additional advantages, features, properties, and aspects of the present invention emerge from the claims and the subsequent description of a preferred embodiment with reference to the drawings.

### BRIEF DESCRIPTION OF THE DRAWINGS

FIG. 1 is a schematic, perspective illustration of a micro electronic component according to the proposal with a plurality of clusters;

FIG. 2 is a schematic, sectional illustration of a cluster with allocated connecting electrodes of the micro electronic component;

FIG. 3 is a schematic illustration of the fabrication process of a tool for fabricating the micro electronic component; and

FIG. 4 is a schematic illustration of the fabrication process of the micro electronic component.

### DESCRIPTION OF THE PREFERRED EMBODIMENTS

For the purposes of promoting an understanding of the principles of the invention, reference will now be made to the embodiments illustrated in the drawings and specific language will be used to describe the same. It will nevertheless be understood that no limitation of the scope of the invention is thereby intended, such alterations and further modifications in the illustrated device, and such further applications of the principles of the invention as illustrated therein being contemplated as would normally occur to one skilled in the art to which the invention relates.

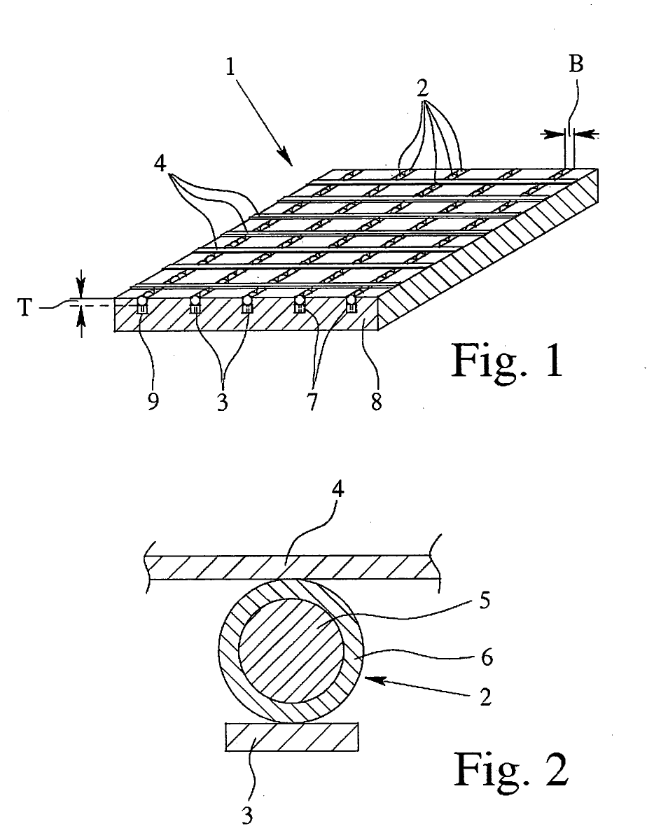

Referring to FIGS. 1-4, it should first be noted that, in the figures, the same reference symbols are used for equivalent or similar parts, wherein corresponding or comparable properties and advantages are achieved even if a description is not repeated, especially due to reasons of simplification.

FIG. 1 shows in a schematic, perspective illustration a micro electronic component 1 according to an especially preferred embodiment. In particular, this embodiment concerns an electronic memory with a plurality of memory cells or transistors, preferably single-electron transistors. However, the micro electronic component 1 can also be used for other purposes.

The micro electronic component 1 has a plurality of clusters 2, which are shown in FIG. 1 in the shape of balls.

The micro electronic component 1 further has first and second connecting electrodes 3, 4 for electrical attachment or contact to clusters 2. This will be discussed in more detail below.

FIG. 2 shows in a schematic, sectional illustration the preferred design of a cluster 2. The cluster 2 has a metallic cluster nucleus 5 and a preferably electrically insulating cluster shell 6.

The cluster nucleus 5 is preferably composed of a transition metal, especially gold. Each cluster nucleus 5 comprises several metal atoms, especially at least 20 and/or a maximum of 100 metal atoms, particularly preferred 55 metal atoms, which are arranged especially in close-packed sphere packing in multiple shells.

However, the cluster nuclei 5 can also be built from a different number of atoms, especially when each cluster nuclei 5 is composed of several transition metals.

The maximum size of the cluster nuclei 5 preferably equals approximately 2.5 nm, especially approximately 2.0 nm, and particularly preferred 1.6 nm; and its minimum size is at least approximately 0.5 nm, especially approximately 1.0 nm, and particularly preferred approximately 1.3 nm. It is particularly preferred when the average size of the cluster nuclei 5 lies in the range from approximately 1.3 nm to approximately 1.5 nm.

The cluster shell 6 is preferably formed so that it is electrically insulating and is composed of organic compounds. However, the cluster shell 6 can also be formed, for example, from inorganic compounds and/or another metal.

Preferably, the cluster shell 6 is composed of suitable ligands, for example, organic radicals or halogens, especially chlorine. Examples of suitable organic compounds are triphenylphosphine and its derivatives.

The clusters 2—thus cluster nucleus 5 and cluster shell 6—preferably have an average diameter of 1-5 nm, especially 2-3 nm, particularly preferred of approximately 2.5 nm.

Especially preferred are clusters 2 with the following formula:
Au₅₅[P(C₆H₅)₃]₁₂Cl₆

The fabrication of the clusters 2 can be easily found in the literature. In particular, one reference is the article mentioned in the introduction and the locations cited therein. Incidentally, the clusters 2 can also be easily purchased in modified form (with different cluster shells 6), for example, under the trade name of Nanogold from Nanoprobe [sic; Nanoprobes, Inc.], USA.

FIG. 2 further shows that the illustrated cluster 2 is connected both to a first connecting electrode 3 and also to a second connecting electrode 4. This represents the ideal or desired configuration and in particular forms a “memory cell” or an individual electronic functional unit of a plurality of equivalent functional units of the micro electronic component 1.

The electronic properties of the cluster nucleus 5 or the cluster 2 do not correspond to those of a metal, but instead more to those of a semiconductor. Thus, a sort of “conductor-semiconductor-conductor” contact is obtained. The cluster 2 forms a tunnel contact with the connecting electrodes 3, 4. Accordingly, electrons can flow between the connecting electrodes 3, 4 and the cluster 2. In particular, single-electron transfers are sufficient to change the electrical state of the cluster 2. Accordingly, a kind of “single-electron transistor”—thus a memory cell or circuit preferably switching with only a single electron—can be formed.

As shown in FIG. 2, in principle the clusters 2 are connected individually to a first and second connecting electrode 3, 4. In particular, a first and a second connecting electrode 3, 4 are basically in electrical contact with each other only by means of at most one cluster 2. Thus, an optimum miniaturization and simpler design, as well as low power and energy requirements, are enabled.

If necessary, not-shown control electrodes, like those typical in transistors, can also be allocated to the connected clusters 2.

The clusters 2 are preferably arranged in lines or rows, especially only in one plane, as shown in FIG. 1. In particular, the clusters 2 are housed in grooves 7 arranged and configured corresponding to this arrangement in a carrier 8 of the micro electronic component 1.

In the preferred embodiment, the grooves 7 essentially have a rectangular cross section and optionally have a curved groove base 9. In particular, this also depends on the fabrication process, which will be discussed in more detail below.

The width B of the grooves 7 is as small as possible, so that the clusters 2 fit as much as possible in only one row and not one next to the other in the grooves 7. Preferably, the maximum width B of the grooves 7 is 5 nm, particularly 4 nm, and advantageously approximately 3 nm.

Preferably, the diameter of the clusters 2 equals at least 50%, particularly at least 70%, of the width B of the grooves 7. In the ideal case, this leads to an at least essentially straight-line chain of clusters 2 in the grooves 7.

In the preferred embodiment, the first connecting electrodes 3 are arranged in the grooves 7, in particular formed directly on the groove bases 9. The maximum remaining clear depth T of the grooves 7 equals preferably 3 nm, particularly 2 nm. In particular, the clear depth T is smaller than the average diameter of the clusters 2. In this way, the clusters 2 housed in the grooves 7 project somewhat out of the grooves 7 in order to simplify the electrical contact to the second connecting electrodes 4 preferably running crosswise to the longitudinal direction of the grooves 7.

In the preferred embodiment, the first connecting electrodes 3 run parallel to each other and in a common plane.

In the preferred embodiment, the second connecting electrodes 4 likewise run parallel to each other in a common plane and crosswise, especially perpendicular, to the first connecting electrodes 3 or the cluster rows or grooves 7.

To achieve the individual bonding of the clusters 2 already explained with reference to FIG. 2, the spacing of the planes of the first and second connecting electrodes 3, 4 corresponds approximately to the average diameter of the clusters 2.

The distance between the grooves 7 or cluster rows 2 is preferably as small as possible. In particular, it equals approximately 5-60 nm. A corresponding situation applies to the distance between the second connecting electrodes 4.

The second connecting electrodes 4 are each formed essentially like connecting elements or strips. The width B is as small as possible and preferably equals a maximum of 4 nm. It particularly equals approximately 3 nm or approximately 50-125% of the average diameter of the clusters 2. Thus, the second connecting electrodes 4 in one groove 7 can each contact as much as possible only a single cluster 2. If two clusters 2 in one groove 7 are contacted simultaneously by a second connecting electrode 4, then this is a defect point or defective memory cell.

As already explained in the introduction, for the shown embodiment, not all of the clusters 2 are contacted, instead only those in the region of the intersecting points between the first and second connecting electrodes 3, 4. The other, non-contacted clusters 2 are then non-critical components for the function of the micro electronic component 1, especially if there are several non-connected clusters 2 in the groove 7 between two adjacent, connected clusters 2 in a groove 7.

Naturally, as an alternative or addition, it is also possible for no other clusters 2 to be arranged between the connected clusters 2 in a groove 7 or for the chain of clusters 2 to be broken, for example, by subsequent elimination or modification of contacted clusters 2 or by corresponding, preferably individual positioning of clusters 2 in suitable, not-shown grooves and recesses, which can be generated, for example, through anodic oxidation of aluminum.

In FIG. 1, only the essential structures of the micro electronic component 1 according to the especially preferred embodiment are shown in order to understand the principle of the proposed design. Obviously, instead of this configuration, other structural solutions and arrangements are possible.

The essential feature is that a plurality of clusters 2 are connected individually to a first and second connecting electrode 3, 4, such that these clusters 2 can be electrically modified or polled independently of each other. In particular, the solution according to the proposal also enables simple addressing of the connected clusters 2 or fabricated memory cells.

To modify the electronic behavior or control, not-shown control electrodes or the like can also be allocated to the connected clusters 2.

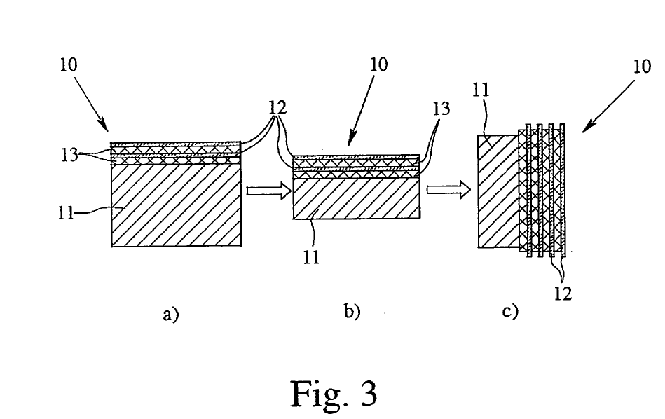

The fabrication of the micro electronic component 1 according to the especially preferred embodiment is described below in more detail. For this purpose, first the fabrication of a tool 10 is described with reference to FIG. 3.

The fabrication of the tool 10 takes advantage of the ability to generate layers of defined thickness, for example through MBE (Molecular Beam Epitaxy), and to use these layers of defined thickness for the fabrication of necessary strip structures.

As indicated in FIG. 3, in step a) alternating layers 12, 13 made from different materials, especially GaAs and AlAs, are formed on a substrate 11, for example Si doped with GaAs. In particular, the thin layers 12 composed of AlAs in the embodiment have a thickness of preferably only approximately 3 nm. The thickness of the thicker layers 13, which here are composed of GaAs, equals approximately 10 to 100 nm. For example, 20 such layer pairs are deposited one after the other, especially through MBE.

Then in step b) at least one side surface is lapped and then selective material is removed, especially through etching (in the embodiment, preferably a solution of citric acid and hydrogen peroxide is used) in order to etch the thicker layers 13 on the sides or in thickness such that the thinner layers 12—in the embodiment the layers 12 made from AlAs—project outwards, especially by approximately 10 to 40 nm.

As an example step c) shows the resulting tool 10 with the thinner layers 12 projecting laterally like connecting elements. The tool 10 then can be used especially as a stamp or die or the like.

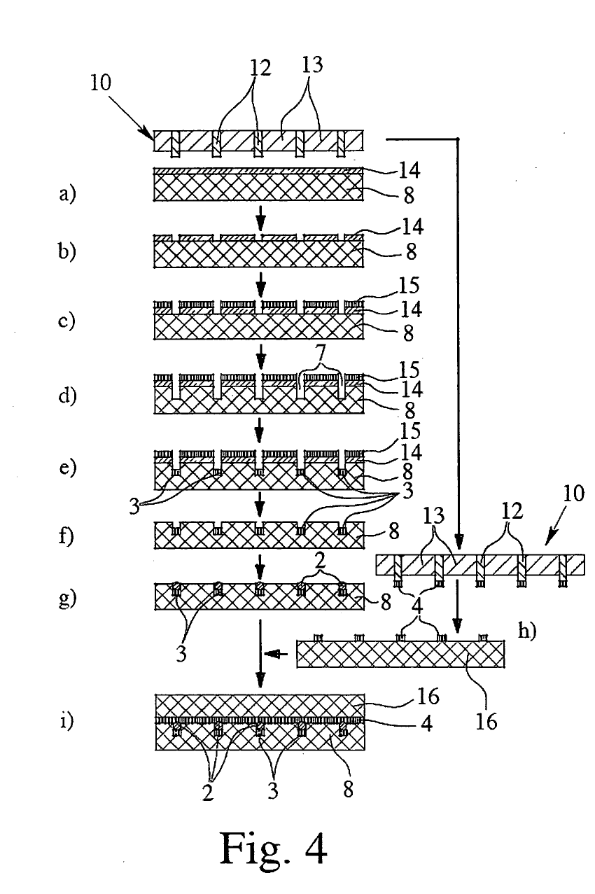

A preferred method for fabricating the micro electronic component 1 is explained below with reference to FIG. 4.

The carrier 8 is preferably composed of silicon or silicon dioxide. In particular, the carrier is a conventional wafer.

In step a) the carrier 8 is provided with a suitable coating 14, especially made from a polymer, preferably the polymer available under the trade name “mr-8010” from www.microresist.de, with a thickness of approximately 20-150 nm. Then, at an increased temperature of, for example, approximately 180° C., the tool 10 with the projecting edges of the layers 12 is pressed into the coating 14, for example with a force of 20-40 cN, for example, for 1-5 min. Here, correct alignment of the tool 10 relative to the surface of the carrier 8 is essential.

After separating the tool 10 from the carrier 8, slots or grooves are produced in the coating 14 at desired distances and with the desired width, as indicated in step b).

Then, in step c) the coating 14 is provided with a cover layer 15, preferably made from gold, especially through oblique vapor deposition.

The cover layer 15 is used as an etching mask in the subsequent etching step d). In particular, dry etching is performed. Thus, the grooves 7 are formed in the carrier 8.

Then, in step e) the first connecting electrodes 3 are formed in the grooves 7. This can be realized, for example, through vapor deposition with a suitable material, such as gold or palladium, or in other suitable ways.

In step f) the layers 14 and 15 are then removed, for example, through ultrasound and/or a suitable solvent, such as acetone.

In step g) the clusters 2 are then arranged in the grooves 7 on the first connecting electrodes 3. This is realized preferably through electrophoresis. For example, the clusters 2 are formed directly by applying a corresponding voltage on the first connecting electrodes 3. Here, it is insignificant that the clusters 2 are in direct contact with each other. Instead, in this way the desired electrical bonding of the clusters 2 with the first connecting electrodes 3 is achieved with very simple means and methods. Furthermore, selective adsorption of the clusters 2 on the connecting electrodes 3 can be realized, especially by providing the first connecting electrodes 3 with a dithiol monolayer or the like.

In step h) the second connecting electrodes 4 are fabricated. In particular, for this purpose the tool 10 or some other tool is used. In the embodiment, the edges of the projecting, thinner layers 12 are coated with an electrically conductive material, especially gold, palladium, platinum, or the like. In this way, the preferably strip-shaped second connecting electrodes 4 are generated.

Preferably, the first connecting electrodes 3 one on hand and the second connecting electrodes 4 on the other hand are composed of electrically different materials or materials of different electronegativity in order to achieve an asymmetrical design in terms of electricity.

The second connecting electrodes 4 are then transferred onto an electrode carrier 16, which is composed especially of a suitable plastic, such as polydimethylsiloxane or the like, by pressing the tool 10 onto the electrode carrier 16. Preferably, the electrode carrier 16 has at least some elasticity and/or ability to deform plastically. In step h) the electrode carrier 16 is shown with the already transferred second connecting electrodes 4.

Finally, in step i) the electrode carrier 16 is pressed together with the second connecting electrodes 4 onto the carrier 8 with the clusters 2 preferably projecting somewhat out of the grooves 7 and is connected with this in a suitable way. The second connecting electrodes 4 running parallel to each other extend crosswise, especially perpendicular, to the cluster rows or grooves 7 and thus also to the first connecting electrodes 3. In this way, the micro electronic component 1 according to the proposal is then completed.

The previously mentioned method can be performed very simply and economically. In particular, the method permits the fabrication of especially small structures that previously could not be achieved practically.

The method according to the proposal can also be used for the fabrication of other micro electronic components, thus, if necessary, independent of the use of clusters 2 or the like. This applies especially in terms of the fabrication of the tool 10 and its possible universal uses for generating very fine structures with parallel channels, edges, grooves 7, connecting electrodes 4, or the like.

In the preferred embodiment, the micro electronic component 1 has a plurality of diode-like memory cells or circuits, which can respond separately electrically and which operate or switch especially with single-electron transfers. For forming transistors, preferably additional (not-shown) control electrodes or other suitable control electrodes are provided, especially in order to form otherwise conventional memory circuits or the like.

While the invention has been illustrated and described in detail in the drawings and foregoing description, the same is to be considered as illustrative and not restrictive in character, it being understood that only the preferred embodiment has been shown and described and that all changes and modifications that come within the spirit of the invention are desired to be protected.

1. Micro electronic component, especially electronic memory, with clusters and with first and second connecting electrodes, wherein the clusters each have a metallic cluster nucleus and preferably an electrically insulating cluster shell, wherein the clusters, if they are connected, are each connected individually to a first and second connecting electrode, such that individually these clusters can be electrically modified or polled independently of each other.

2. Component according to claim 1, wherein the clusters are arranged in lines or rows, especially in only one plane, or individually, especially in recesses.

3. Component according to claim 1, wherein the component has grooves, in which the clusters are housed preferably individually.

4. Component according to claim 3, wherein the grooves have essentially rectangular cross sections with optionally curved groove bases.

5. Component according to claim 3, wherein the average diameter of the clusters equals at least 50%, especially at least 70%, of the width of the grooves.

6. Component according to claim 3, wherein the clear depth of the grooves is smaller than the average diameter of the clusters.

7. Component according to claim 3, wherein the first connecting electrodes run along the grooves or are arranged in these grooves.

8. Component according to claim 3, wherein the clusters project from the grooves for electrical bonding by the second connecting electrodes.

9. Component according to claim 1, wherein the second connecting electrodes are spaced part in a common plane and run crosswise to the first connecting electrodes.

10. Component according to claim 1, wherein the first and/or second connecting electrodes are pressed to the clusters for electrical bonding.

11. Component according to claim 1, wherein the first and/or second connecting electrodes each form a tunnel contact with the contacted clusters.

12. Component according to claim 1, wherein a first and second connecting electrode each form, together with a bonded cluster, a single-electron transistor and/or are in electrical contact with each other by means of at most one cluster.

13. Component according to claim 1, wherein the first connecting electrodes on one hand and the second connecting electrodes on the other hand are composed of different materials.

14. Component according to claim 1, wherein the clusters are spherical or elongated.

15. Component according to claim 1, wherein the average diameter of the clusters equals a maximum of 5 nm.

16. Component according to claim 1, wherein the cluster nuclei are composed of a transition metal, especially gold.

17. Component according to claim 1, wherein the cluster nuclei are each composed of at least 20 and/or at most 100 metal atoms, especially 55 metal atoms.

18. Component according to claim 1, wherein the cluster shells are each formed from organic ligands.

19. Method for fabricating a micro electronic component, wherein clusters with a metallic cluster nucleus and preferably an electrically insulating cluster shell are connected to first and second connecting electrodes,
wherein the clusters, if they are electrically connected, are connected individually to the first and second connecting electrode, such that individually these clusters can be electrically modified independently of each other through single-electron transfers between cluster and connecting electrode,
wherein the clusters are formed by electrophoresis on the first connecting electrode,
wherein the clusters are arranged in parallel grooves essentially in lines or rows or are housed individually in recesses, and/or
wherein the first and second connecting electrodes are strip-shaped and arranged such that the first connecting electrodes each run parallel to each other and the second connecting electrodes each run parallel to each other and crosswise to the first connecting electrodes, wherein a first and a second connecting electrode are each brought into electrical contact with each other at their appropriate intersecting point by means of preferably a single cluster.

20. Method according to claim 19, wherein the first connecting electrodes are formed in the grooves.
